(19) United States
(12) Patent Application Publication
(10) Pub. No.: US 2009/0321849 A1
(43) Pub. Date: Dec. 31, 2009

(54) SEMICONDUCTOR DEVICE, INTEGRATED CIRCUIT, AND SEMICONDUCTOR MANUFACTURING METHOD

(75) Inventors: Makoto Miyamura, Tokyo (JP); Kiyoshi Takeuchi, Tokyo (JP)

Correspondence Address: YOUNG & THOMPSON, 209 Madison Street, Suite 500, Alexandria, VA, 22314, US

(73) Assignee: NEC CORPORATION, Tokyo (JP)

(21) Appl. No.: 12/302,121

(22) PCT Filed: May 23, 2007
(86) PCT No.: PCT/JP2007/060559

§ 371 Date: Jan. 16, 2009

(30) Foreign Application Priority Data
May 23, 2006 (JP) 2006-142249

(51) Int. Cl. H01L 27/088; H01L 21/8234

(52) U.S. Cl. 257/392; 438/277; 257/E27.061; 257/E21.618

(57) ABSTRACT

A semiconductor circuit has a plurality of MISFETs formed with channel films comprised of semiconductor layers on an insulation film. Channel film thicknesses of each MISFET are different. A correlation relationship is fulfilled where concentration per unit area of impurity contained in the channel films becomes larger for MISFETs of a thicker channel film thickness. As a result, it is possible to suppress deviation of threshold voltage caused by changes in channel film thickness. In this event, designed values for the channel film thicknesses of the plurality of MISFETs are preferably the same, and the difference in channel film thickness of each MISFET may depend on statistical variation from the designed values. The concentration of the impurity per unit area is proportional to the channel film thickness, or is a function that is convex downwards with respect to the channel film thickness.

### TECHNICAL FIELD

The present invention relates to a semiconductor device, an integrated circuit, and a method for manufacturing a semiconductor device suitable for lowering variation in a threshold voltage of a MISFET (Metal Insulator Semiconductor Field Effect Transistor) having a thin-film channel.

### BACKGROUND ART

In order to improve various characteristics of a large-scale integration circuit such as increasing the degree of integration and increasing the speed of operation, MOS Field Effect Transistors (MOSFET: Metal Oxide Semiconductor Field Effect Transistor), that are a basic configuration element of a large-scale integration (LSI: Large Scale Integration) circuit, are being miniaturized. This miniaturization is carried out in accordance with scaling that simultaneously reduces three-dimensional dimensions of the elements.

An important requirement of MOSFET scaling is that, together with the miniaturization of the actual three-dimensional dimensions, a potential difference in a lateral direction linking a source and drain of an FET (Field Effect Transistor) and a potential difference in a vertical direction as viewed in a depth direction from a gate electrode are simultaneously reduced so that the electric field intensity itself within the element is held fixed. This reduction of the power supply voltage (Vdd) by carrying out scaling has the effect of reducing the operating power of the MOSFET. This means that LSI performance can be increased year-by-year.

On the other hand, it is also necessary to reduce the threshold voltage (Vth) in order to ensure current (Ion) during operation due to the influence of lowering Vdd. Lowering of the threshold voltage causes an increase in sub-threshold leakage current flowing across the source and drain when the FET is off. As a result, the benefits of reduced power consumption of the LSI in lowering Vdd is degraded. With the generation of devices where channel length is 0.1 microns or less, electrostatic coupling of the source region and the drain region is stronger (short channel effect). Subthreshold leakage current therefore increases substantially. This is a major factor in preventing miniaturization of devices.

Various methods of suppressing subthreshold leakage have been proposed. In particular, thin-film channel MISFETs of a thin channel film thickness are capable of suppressing short channel effects and are capable of reducing subthreshold leakage current compared to bulk type MISFETs of the related art. FinFETs (Fin Field Effect Transistors), SOI (Silicon on Insulator) FETs, planar double-gate FETs, and omega-gate-FETs etc. have been proposed as publicly known thin-film channel MISFETs.

However, with thin-film channel MISFETs, it is necessary to simultaneously make the film thickness of the thin-film channel region thinner in order to suppress short channel effects while advancing miniaturization of gate length. For example, it is necessary to maintain a channel film thickness in the order of ¼ of the gate length with fully depleted type SOI-MISFETs.

Not only the manufacturing of thin-film channel MISFETs having a thin channel film thickness become difficult, but also variation in element characteristics of the device become substantial with respect to deviation in channel film thickness.

Various methods have been proposed in order to suppress Vth deviation due to variation in channel film thickness. For example, in patent document 1, a method is disclosed of reducing impurity concentration of an SOI channel region from an upper region to a lower region. According to this method, it is possible to keep total deviation of impurities within the thickness of the channel film below with respect to channel film thickness.

In patent document 2, a method is shown of suppressing deviation of Vth by providing a fixed charge layer in an embedded oxide film layer at a depth corresponding to a channel film thickness.

In patent document 3, a semiconductor apparatus is disclosed that corrects Vth deviation by applying a voltage to a back gate via a storage element that stores channel film thickness and impurity concentration for an integrated circuit comprised of SOI MISFETs.

Patent Literature 1: Japanese Patent Application KOKAI Publication No. 2004-289001

Patent Literature 2: Japanese Patent Application KOKAI Publication No. 2002-299634

Patent Literature 3: Japanese Patent No. 3585912

Non-patent Document 1: Kiyoshi Takeuchi, Toru Tatsumi, Akiko Furukawa et. al, “Channel Engineering for the Reduction of Random-Dopant-Placement-Induced Threshold Voltage Fluctuation”, IEDM Tech. Dig., 1995, p. 67-70

### DISCLOSURE OF THE INVENTION

### Problems to be Solved by the Invention

However, the related art described above has the problems shown below.

In patent documents 1 and 2, suppression of the deviation of Vth mainly considers transistors of a sufficiently long gate length, i.e. so-called long channel transistors. Lowering of Vth in short channel transistors (short channel effects, or DIBL (Drain Induced Barrier Lowering)) depends on channel film thickness. In patent documents 1 and 2, such deviating components are not considered. If Vth deviation of short channel transistors that occupy a large proportion of semiconductor circuits can not be suppressed, the advantages of an SOI structure are critically reduced.

As shown in patent document 3, technology has been considered that accurately corrects Vth deviation in semiconductor devices equipped with a circuit that controls substrate potential. This does, however, worryingly cause circuit overhead to increase substantially. Such means cannot be utilized by thin-film channel MISFETs that cannot form back gates such as FinFETs.

It is well known that variation in channel film thickness causes Vth to fluctuate in thin-film channel MISFETs so as to cause variation in device characteristics. However, it is not possible to suppress deviation in Vth caused by change in channel film thickness particularly for short channel transistors using a straightforward method of the publicly known methods.

In order to resolve the above problems, it is an object of the present invention to provide a semiconductor device, an integrated circuit, and a method for manufacturing a semiconductor device, capable of suppressing deviation of a threshold voltage caused by change in channel film thickness at a thin-film channel MISFET.

### Means for Resolving the Problem

An integrated circuit of the present invention has a plurality of MISFETs that include: a semiconductor layer having a channel region provided between a source and a drain, the semiconductor layer being formed on an insulation film, a gate insulation film being in contact with the channel region; and a gate being in contact with the gate insulation film. Here, the channel region contains impurities of such a volume concentration that a standard deviation σVth of a threshold voltage, which changes due to variation of the thickness of the channel region and variation of the impurities, becomes a minimum. Here, such volume concentration that a standard deviation σVth of a threshold voltage becomes a minimum is within a range that accords to a gate length of the gate.

In this event, it is preferable for design values of thicknesses of the respective channel regions of the plurality of MISFETs to be the same as each other, and for the difference in the thickness of the channel region among the respective MISFETs to depend on the statistical variation from a design value.

Further, volume concentration Nch for the impurity that makes the standard deviation σVth of the threshold voltage minimum for a gate length L of a range of 15 to 80 nm is preferably within a range that accords to the gate length and that satisfies −c≦log 10(Nch)+a·log 10(L)−b≦c (where a=1.33, b=19.9, and c=0.4).

One surface of the channel region of each of the MISFETs is in contact with the gate insulation film and an other surface thereof is in contact with the insulation film, and volume concentration of the impurities in a depth direction from said one surface is preferably constant regardless of the depth.

One surface of the channel region of each of the MISFETs is in contact with the gate insulation film and an other surface thereof is in contact with the insulation film, and volume concentration of the impurities at a region in vicinity to said other surface of the channel region is higher than that at the region in vicinity to said one surface of the channel region. The volume concentration at a region in proximity to said other surface of the channel region is preferably a volume concentration that makes the standard deviation σVth of the threshold voltage a minimum.

Each of the MISFETs is preferably double-gate FET, and the volume concentration of the impurities in a film thickness direction from said one surface of the channel region is preferably low in the vicinity of said one surface of the channel region and high in the vicinity of said other surface.

Each of the MISFETs can be FinFET, and the volume concentration of the impurities is low in the vicinity of both surfaces and high at a median point that is equidistant from both surfaces.

A method of manufacturing a semiconductor device of the present invention is a method of manufacturing a semiconductor device having a plurality of MISFETs that include: a semiconductor layer having a channel region provided between a source and a drain, the semiconductor layer being formed on an insulation film, a gate insulation film being in contact with the channel region; and a gate being in contact with the gate insulation film, the method comprising a step of introducing impurities of such a volume concentration that a standard deviation σVth of a threshold voltage, which changes due to variation of the thickness of the channel region and variation of the impurities, becomes a minimum. Here such volume concentration that a standard deviation σVth of a threshold voltage becomes a minimum is within a range that accords to a gate length of the gate.

The step of introducing the impurities can also be implemented by performing ion injection a plurality of times at different average range distances.

The step of introducing the impurities can also include ion injection in which average range distance of ion is larger than the thickness of the channel region.

Each of the MISFETs is FinFET, and in the step of introducing the impurities, ion injection is implemented from one surface of the channel region and the step of introducing the impurities includes ion injection in which average range distance of ion is larger than the thickness of the channel region.

A method of manufacturing a semiconductor device further comprises a channel film growth step of growing the channel film by epitaxial growth. Here, the step of introducing the impurities can also be carried out at the same time as the channel film growth step by concurrently supplying a silicon material and an impurity material.

The step of introducing the impurities can also include a step of forming a sacrificial oxide film being in contact with both surfaces of the channel region and externally dispersing the impurities from both surfaces of the channel region to the sacrificial oxide film, to lower the volume concentration of the impurities in the region in vicinity to both surfaces of the channel region.

### EFFECTS OF THE INVENTION

According to the present invention, with an integrated circuit having a plurality of MISFETs formed from semiconductor layers on an insulation film, it is possible to suppress the effects of variation of a threshold voltage caused by the influence of statistical variation from designed values for channel film thickness and variation of volume concentration in a depth direction from a channel film surface of the impurities.

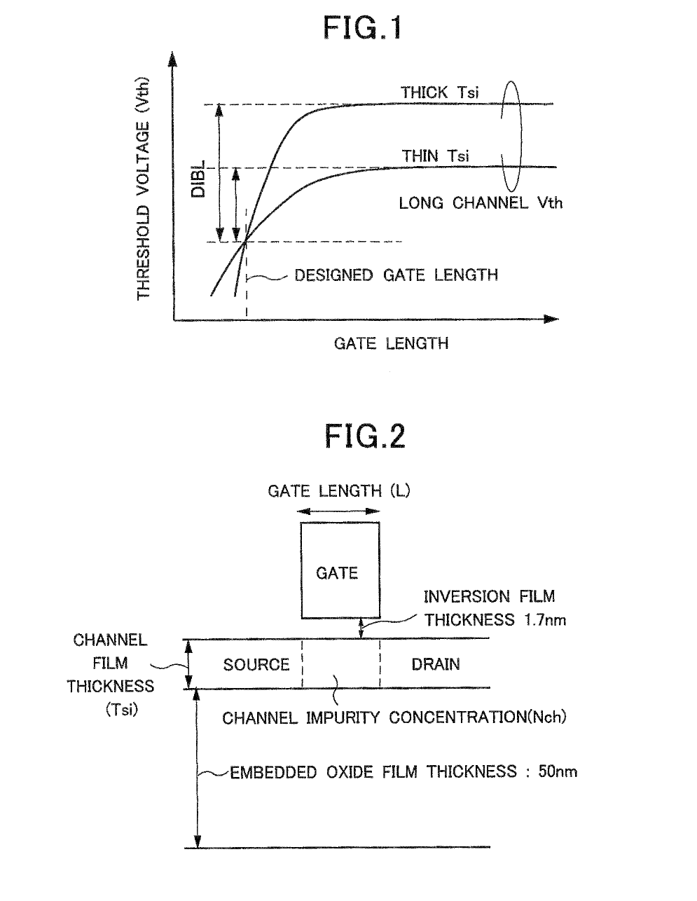

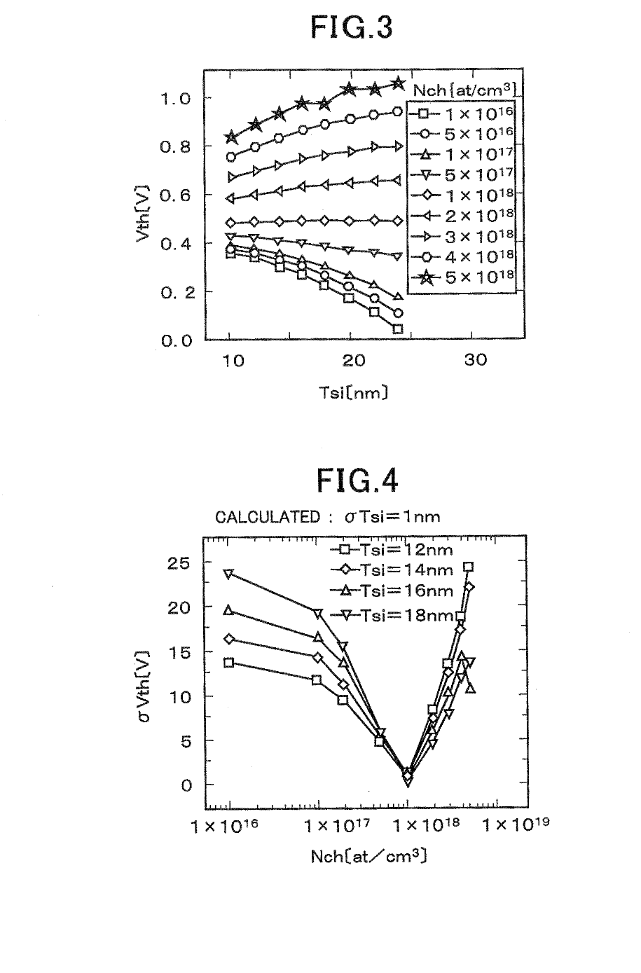

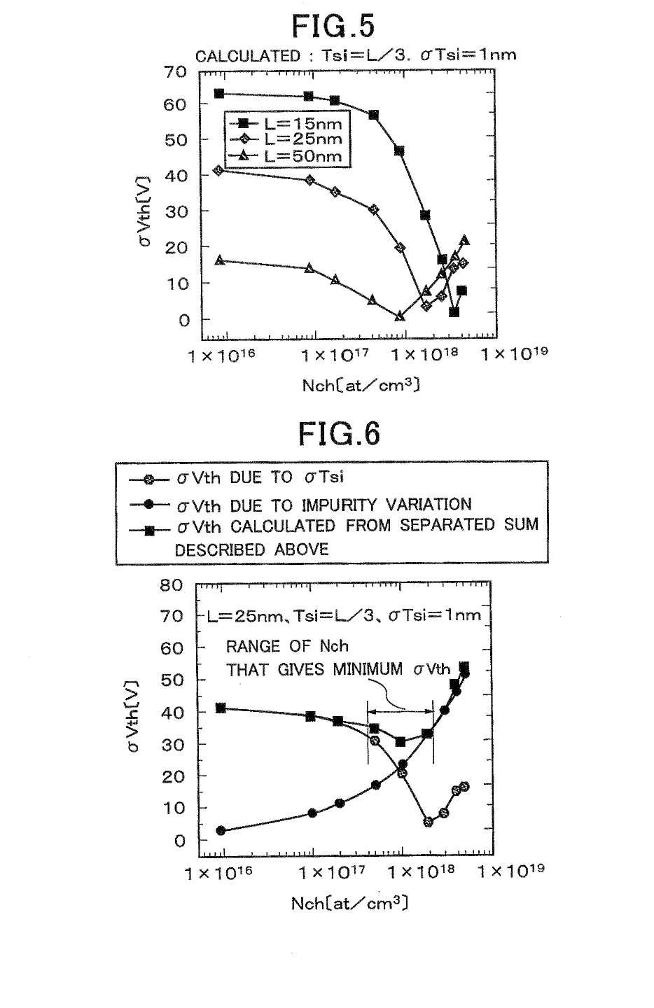

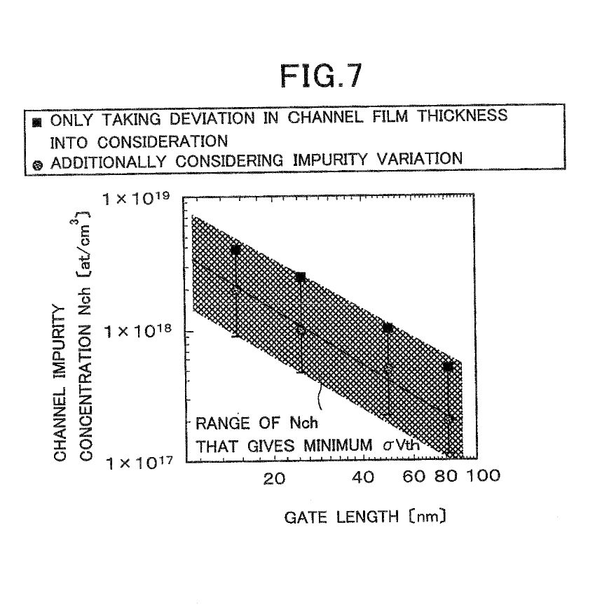

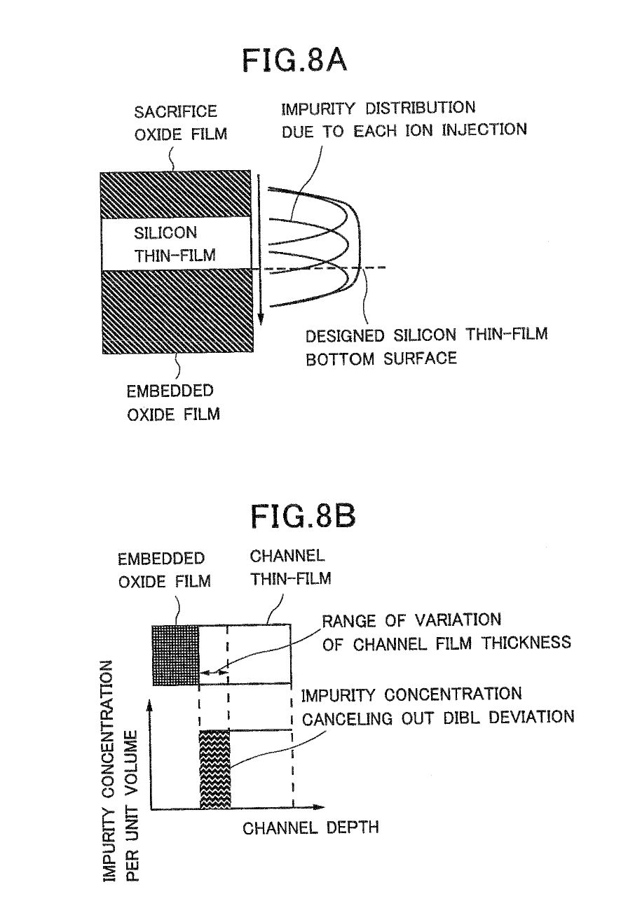

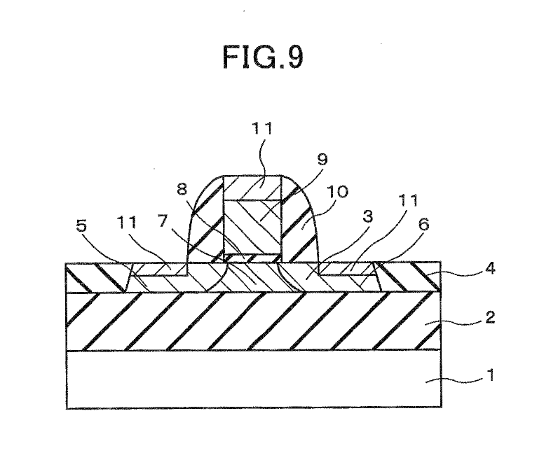

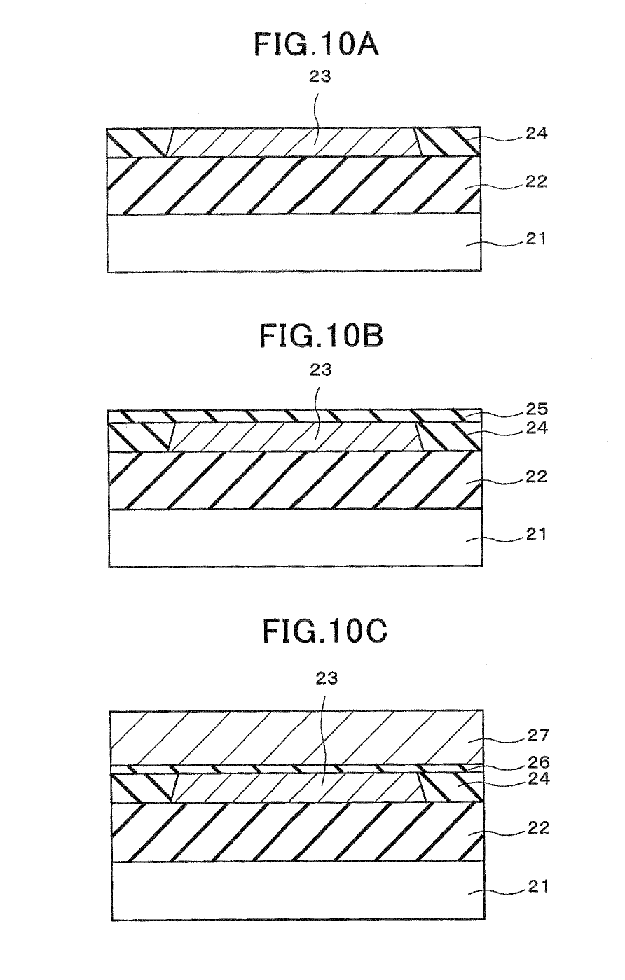

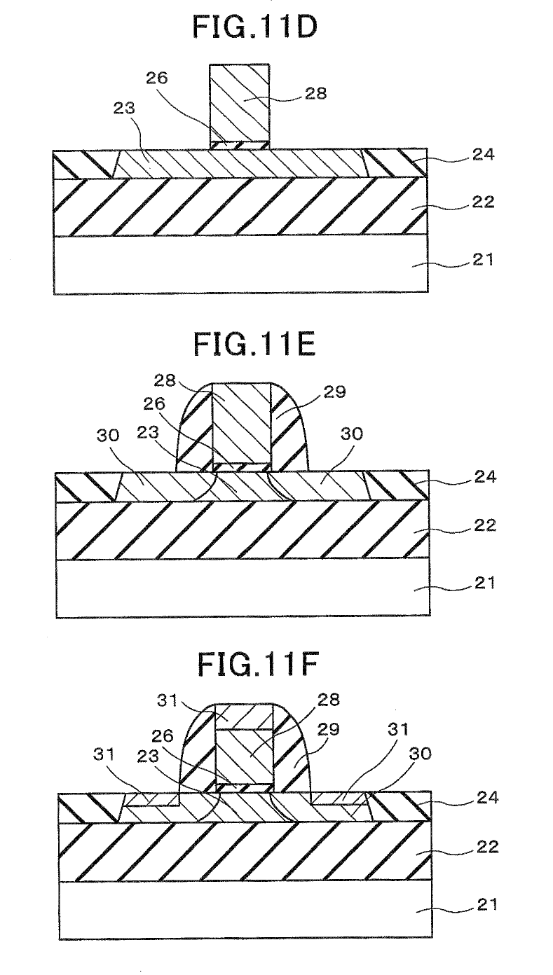

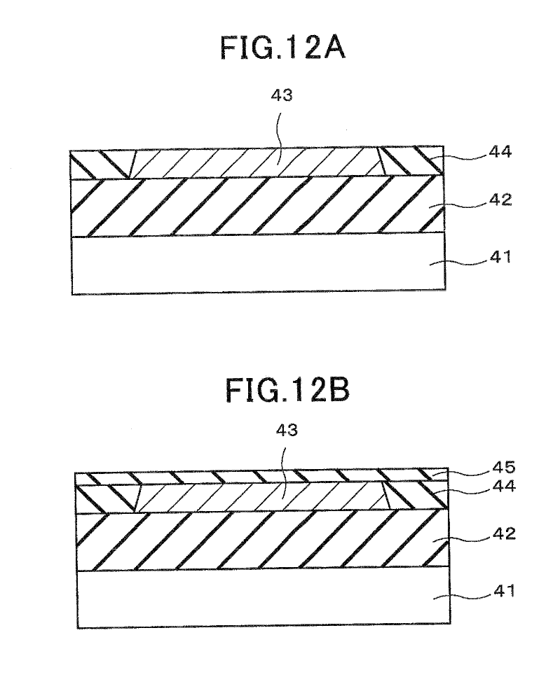

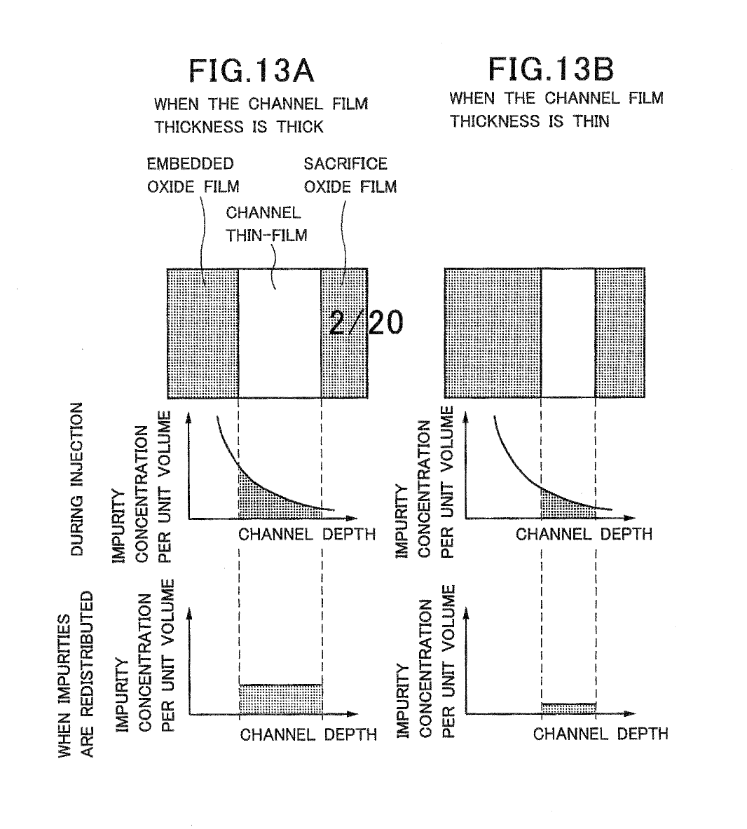

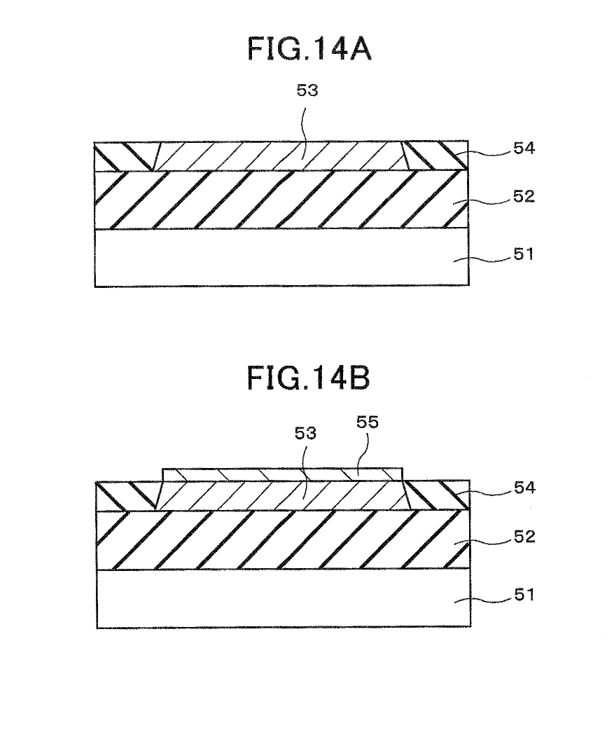

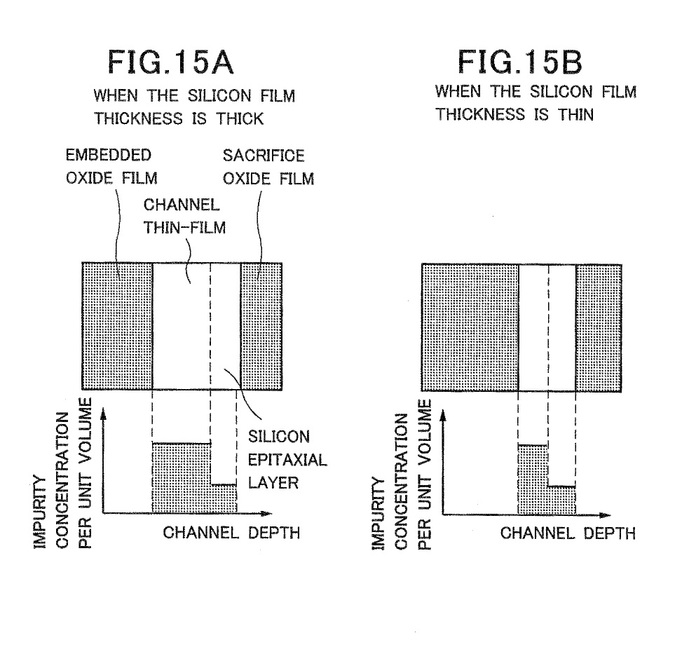

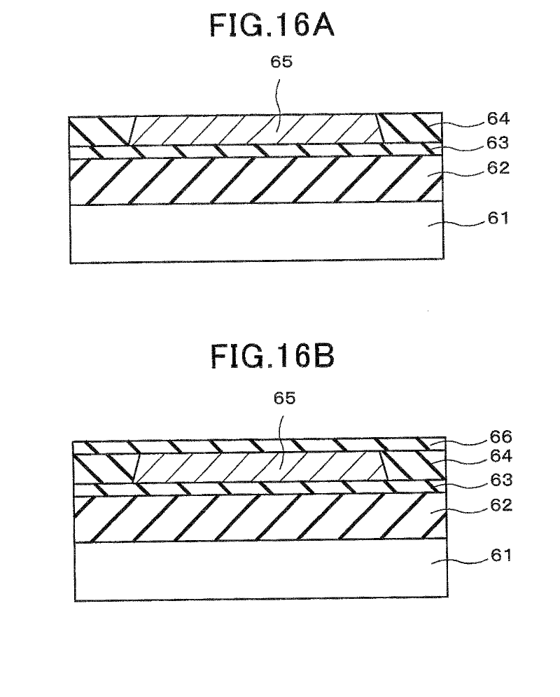

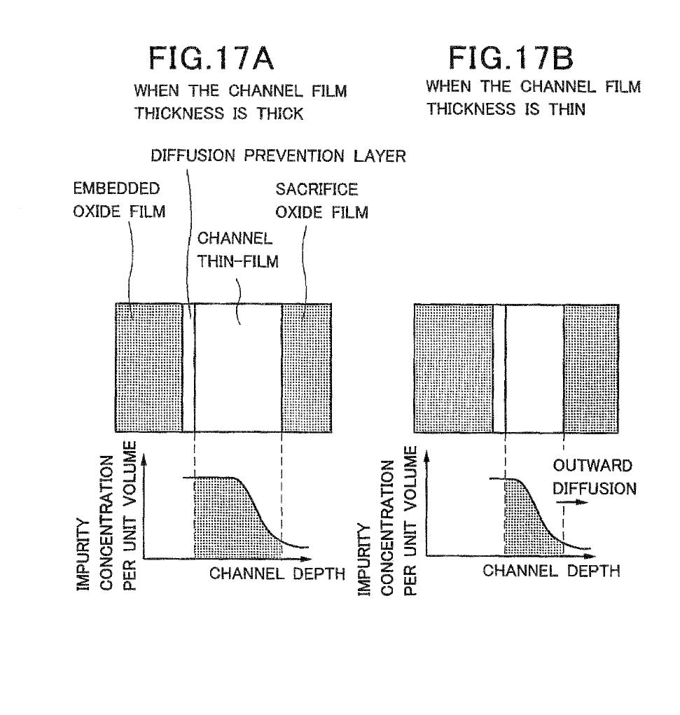

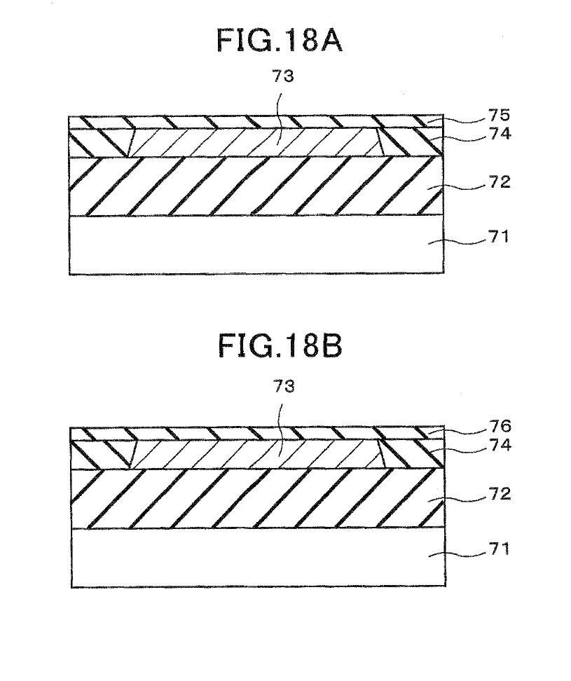

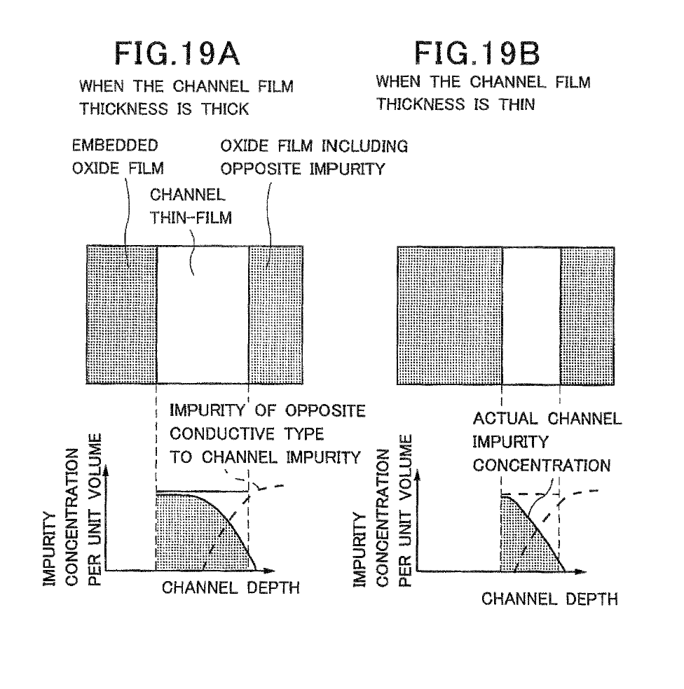

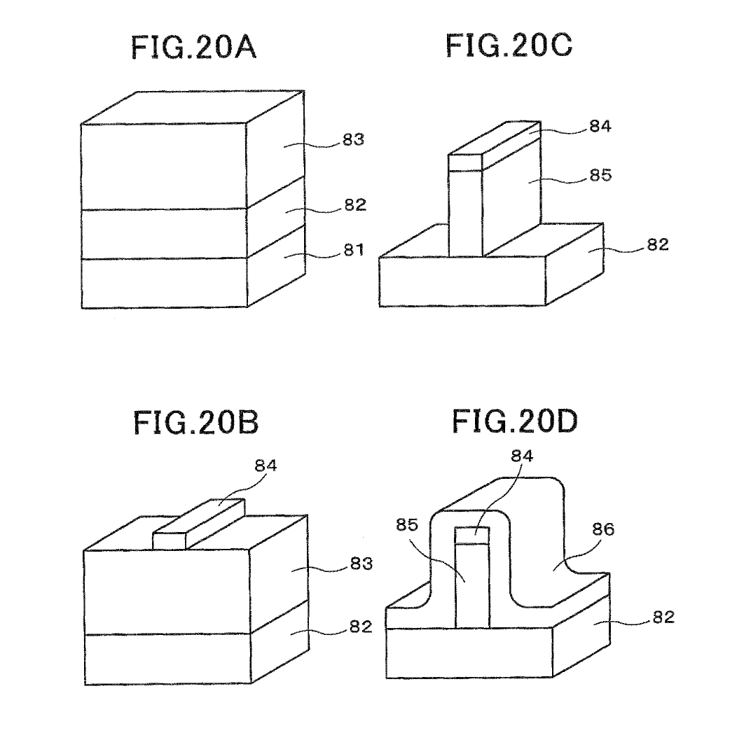

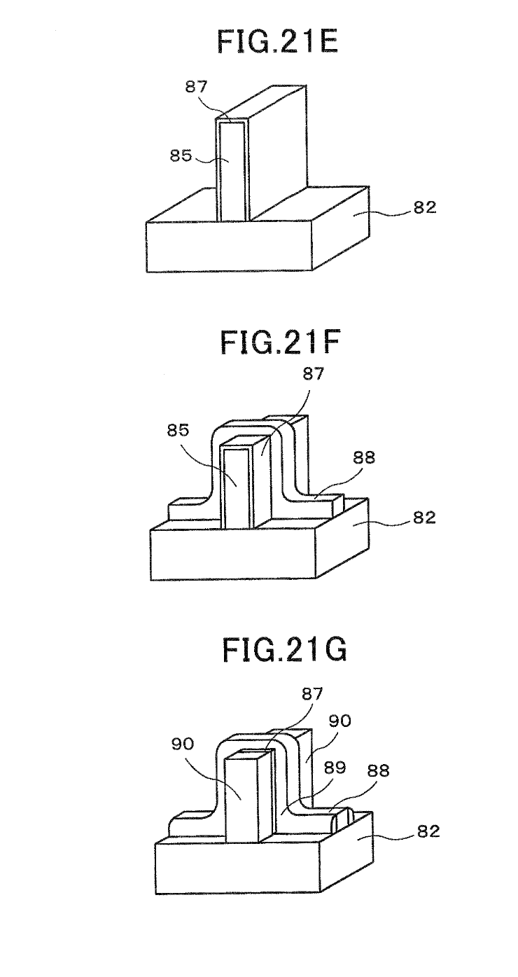

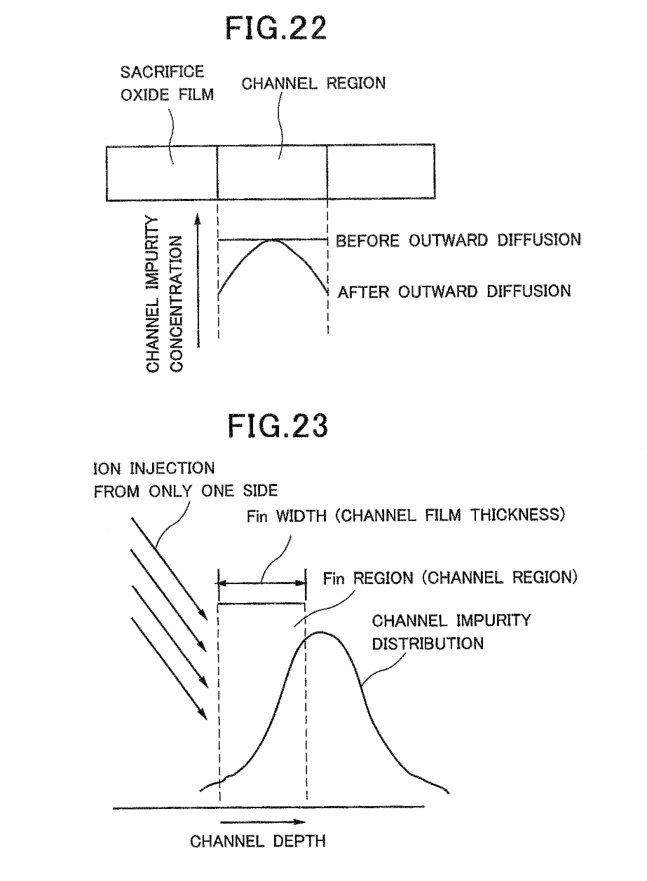

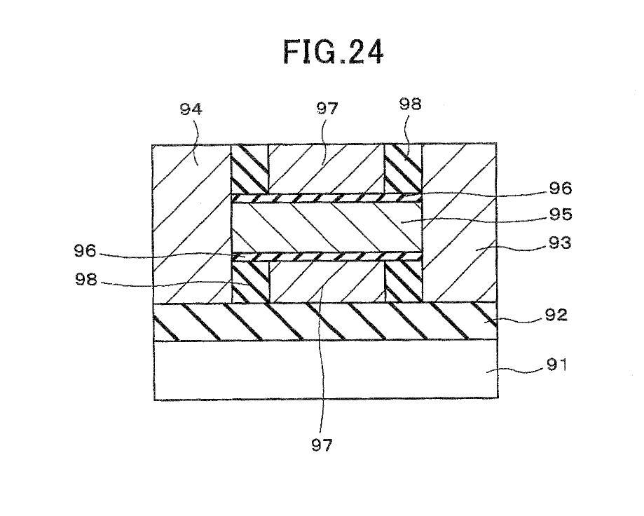

### BRIEF DESCRIPTION OF THE DRAWINGS

[FIG 1] A diagram showing a relationship between gate length and threshold voltage with respect to film thickness.

[FIG. 2] A schematic diagram showing a device structure and parameters used in order to simulate threshold voltage of an SOI MISFET.

[FIG. 3] A diagram showing the relationship between a channel film thickness and a threshold voltage for each of the conditions for uniform channel impurities.

[FIG. 4] A diagram showing a relationship between channel impurity concentration and threshold voltage variation occurring for σTsi=1 nm with respect to a plurality of designed values for Tsi.

[FIG. 5] A diagram showing a relationship between channel impurities and threshold value variation with respect to a plurality of designed gate lengths.

[FIG. 6] A diagram showing a relationship between channel impurities and threshold voltage variation taking into consideration each of the factors of statistical variation in channel film thickness and random variation of impurity position.

[FIG. 7] A diagram showing a channel impurity concentration region for which Vth variation becomes extremely small with respect to designed gate length when the respective factors of statistical variation in channel film thickness and random variation in impurity position are taken into consideration.

[FIG. 8A] A diagram showing a method for injecting ions into a thin-film channel region of a first embodiment of the present invention.

[FIG. 8B] A diagram showing channel doping effects for the first embodiment of the present invention.

[FIG. 9] A cross-sectional view showing a configuration for a thin-film channel MISFET of the first embodiment of the present invention.

[FIGS. 10A to 10C] Cross-sectional views showing an order of steps of a method for manufacturing a semiconductor device of a second embodiment of the present invention;

[FIGS. 11D to 11F] Cross-sectional views showing the order of steps of the method for manufacturing of the second embodiment, continuing on from FIG. 10.

[FIGS. 12A and 12B] Cross-sectional views showing an order of steps of a method of manufacturing a semiconductor device of a first modified example of the second embodiment of the present invention.

[FIG. 13] A diagram showing a method for introducing impurities to a thin-film channel region of the first modified example of the second embodiment of the present invention.

[FIGS. 14A and 14B] Cross-sectional views showing an order of steps of a method for manufacturing a semiconductor device of a second modified example of the second embodiment of the present invention.

[FIG. 15] A diagram showing a method for introducing impurities to a thin-film channel region of the second modified example of the second embodiment of the present invention.

[FIGS. 16A and 16B] Cross-sectional views showing an order of steps of a method of manufacturing a semiconductor device of a third modified example of the second embodiment of the present invention.

[FIG. 17] A diagram showing a method for introducing impurities to a thin-film channel region of the third modified example of the second embodiment of the present invention.

[FIGS. 18A and 18B] Cross-sectional views showing an order of steps of a method of manufacturing a semiconductor device of a fourth modified example of the second embodiment of the present invention.

[FIG. 19] A diagram showing a method for introducing impurities to a thin-film channel region of the fourth modified example of the second embodiment of the present invention.

[FIGS. 20A to 20D] Cross-sectional views showing an order of steps of a method for manufacturing a semiconductor device of a third embodiment of the present invention.

[FIGS. 21E to 21G] Cross-sectional views showing the order of steps of the manufacturing method of the third embodiment, continuing on from FIG. 20.

[FIG. 22] A diagram showing a method for introducing impurities to a thin-film channel region of the third embodiment of the present invention.

[FIG. 23] A diagram showing the introduction of impurities from a fin piece-side to a thin-film channel using ion injection techniques in the third embodiment of the present invention. [FIG. 24] A cross-sectional view showing a configuration for a planar double-gate FET of a fourth embodiment of the present invention.

### EXPLANATION OF REFERENCE NUMERALS

1, 91 semiconductor substrate
2, 22, 42, 52, 62, 72, 82, 92: embedded oxide film
3, 23, 43, 53, 65, 73; silicon thin-film
4, 24, 44, 54, 64, 74; element separation region
5, 6; diffusion layer
7; channel region
8, 26, 96; gate insulation film
9, 28, 97; gate electrode
10, 89; sidewall
11; silicide region
21, 41, 51, 61, 71, 81; silicon substrate
25, 45, 66, 75; sacrifice oxide film
27; electrode layer
30; impurity diffusion region
55; silicon epitaxial layer
63; diffusion prevention layer
66, 75, 86; sacrifice oxide film layer
76; oxide film layer
83; silicon film
84; hard mask
85; fin
87; gate oxide film
88; gate electrode
90; source/drain diffusion region
93; source region
94; drain region
95; thin-film channel region
98; gate sidewall

### BEST MODE FOR CARRYING OUT THE INVENTION

The following is a detailed description with reference to the drawings of embodiments of the present invention. A description is given of each of the embodiments after first describing the features of the present invention. In the following, “integrated circuit” refers to that having a plurality of MISFETs, whereas “semiconductor device” refers to that having one or a plurality of MISFETs. In particular, the method of introducing impurities to the channel film and the impurity concentration described in the following naturally holds for a semiconductor device having one MISFET.

First, in the following, a description is given taking an example of a planar SOI-type MISFET where the impurity concentration of the channel region is fixed as a specific example in order to describe the features of the present invention in detail. However, it is also possible to achieve the same results as with the plane type SOI type MISFET with other publicly known MISFETs having thin-film channels such as a FinFET, a double-gate MISFET, or a surrounding gate MISFET, that operate with the channel region completely depleted.

FIG. 1 is a diagram showing the relationship between gate length and threshold voltage with respect to film thickness. FIG. 1 shows the relationship between gate length and threshold voltage for when the channel film thickness of the MISFET is thick (thick Tsi, Tsi: channel film thickness), and when the channel film thickness is thin (thin Tsi). Conceptually, as shown in FIG. 1, at the designed gate length, the impurity concentration is decided in such a manner that change in length channel Vth is cancelled out when DIBL changes due to deviation in channel film thickness Tsi. Here, change in the long channel Vth is a difference between a threshold voltage for a thick Tsi and a threshold voltage for a thin Tsi when the gate length is made long. In order to investigate the relationship between impurity concentration and designed gate length, device structure parameters such as shown in FIG. 2 (L: gate length, Tsi: channel film thickness, Nch: channel impurity concentration) are respectively changed and an N-type MOSFET threshold voltage Vth is calculated using device simulation. Here, Vth is defined using a gate voltage where a current Ids across a source and drain is given by:

Ids=1×10⁻⁷×L/W[A] [Equation 1]

Where, W is gate width. Further, a work function of a gate electrode uses a value corresponding to a mid-gap of Si (silicon). The potentials of a source region and a support substrate are taken to be 0V and the potential of a drain region is taken to be 1V. Describing the details of FIG. 2, a semiconductor layer is formed on an embedded oxide film of a film thickness of 50 nm. This semiconductor layer is comprised of a source region, a drain region, and a channel region sandwiched between the source region and the drain region. Channel impurities are introduced at a concentration Nch at a channel region of the channel film thickness Tsi. A gate is then formed at the top of the channel region via an inversion film 1.7 nm thick. The length of the gate is L.

For example, dependency of Vth with respect to the channel film thickness Tsi and the channel impurity concentration Nch can be obtained as shown in FIG. 3 taking the results of calculations in the case of L=50 nm. The channel impurity concentration Nch is a volume concentration. According to FIG. 3, when the impurity concentration falls so as to approach zero, dependency of Tsi becomes large (i.e. the threshold voltage Vth also increases as the film thickness Tsi increases). It improves as the impurity concentration increases. In particular, Vth no longer has the dependency of Tsi because in this example, when the channel impurity concentration Nch is made to be in the order of 1×10¹⁸ at/cm³ (at: atomicity). When the impurity concentration is further increased, the dependency of Tsi again increases (i.e., the threshold voltage Vth reduces as the film thickness Tsi increases). When the impurity concentration is lower than 1×10¹⁸ at/cm³, Vth falls on the Tsi thick film side mainly due to DIBL. When the impurity concentration is higher than 1×10¹⁸ at/cm³, Vth increases on the Tsi thick film side due to increases in the quantity of channel impurities.

In FIG. 4, a relationship of channel impurity concentration Nch and σVth (standard deviation of Vth variation) occurring for σTsi (standard deviation of Tsi variation)=1 nm for the case where L=50 nm is shown for each film thickness (Tsi=12 nm, 14 nm, 16 nm, 18 nm). As shown in FIG. 4, impurity concentration that gives a minimum for σVth is decided substantially uniformily regardless of the value of Tsi and can be understood to be in the order of 1×10¹⁸ at/cm³. Similarly, the relationship of channel impurity concentration and σVth is shown in FIG. 5 (calculated taking σTsi=1 nm, Tsi=L/3) for L=15, 25, and 50 nm. As shown in FIG. 5, it can be understood that there is a tendency that Nch minimizing σVth increases as L becomes smaller.

On the other hand, when the channel impurity concentration becomes too high, it becomes no longer possible to ignore the variations in Vth due to the effects of the position of impurities within a depletion layer varying randomly (impurity variation). In the present invention, the channel film thickness is assumed to be sufficiently thin compared to the embedded oxide film thickness. Variation of Vth is therefore estimated using the following equation 2 with reference to non-patent document 1 in order to represent variation of the Vth of a MOSFET of an SOI.

$$σ {V}_{th} = \frac{q}{{C}_{ox}} \sqrt{\frac{{N}_{ch} {T}_{si}}{LW}} \qquad [ Equation 2 ]$$

Here, “q” is charge content and Cox is inversion capacity of the gate insulation film.

A relationship of W=2×L close to the dimensions of the cell transistors used in the SRAM (Static Random Access Memory) circuit is assumed. In addition to σVth that is a cause of deviation in Tsi at L=25 nm, as shown in FIG. 5, the influence of impurity variation is also depicted in the drawings in a superimposed manner as shown in FIG. 6. In FIG. 6, a distributed sum that is an aggregate of the causes of both statistical variation of Tsi and impurity variation is calculated. The obtained σVth is then shown in the drawings in a superimposed manner. When the impurity variation is considered in this manner, an optimum channel impurity concentration that minimizes σVth is shifted to the low concentration side.

An optimum channel impurity concentration range that minimizes σVth as described above is shown in FIG. 7 for a gate length L of L=15 nm to L=80 nm. Namely, a channel impurity concentration range that minimizes σVth when considering only channel film thickness deviation, and a channel impurity concentration range that minimizes σVth when additionally taking into consideration impurity variation are shown in FIG. 7. From the above, it is clear that an optimum channel concentration range can be decided by mainly taking into consideration gate length to make dependency with respect to parameters such as Tsi small. A relationship between gate length L[nm] and channel impurity concentration Nch[at/cm³] that ensures inclusion of the optimum concentration range as shown in FIG. 7 is given by equation 3 below.

log₁₀(Nch)=−1.33·log₁₀(L)+19.9±0.4 [Equation 3]

In this specific example, when the impurity concentration per unit volume of the channel thin-film is fixed, the impurity concentration [at/cm²] per unit area contained in the channel is proportional to the channel film thickness. When channel film thickness statistically varies, the impurity concentration per unit area contained in the channel of each thin-film channel MISFET therefore becomes larger as the channel film thickness becomes thicker.

The specific example described above is discussed assuming a planar SOI type MISFET. However, the same discussion is also possible for other thin-film channel MISFETs such as FinFETs, planar double-gate FETs, or surrounding gate FETs etc. The optimum channel impurity concentration for these structures also roughly obeys equation 3.

In the specific example described above, the discussion proceeds assuming that the impurity concentration per unit volume within the channel thin-film is both uniform and fixed. However, a similar discussion can also be held by assuming that the impurity concentration within the channel thin-film is a so-called retrograde structure where the concentration becomes more concentrated in a depth direction from the channel surface. It is also possible for the DIBL variation to be canceled out by not introducing impurities to the channel surface and only introducing impurities to the bottom surface of the channel thin-film. In this case also, it is possible to design the impurity concentration per unit volume of the bottom surface of the channel to obey equation 3. By doing this, because it is possible to suppress the variation of Vth due to deviation of DIBL by using a smaller quantity of channel impurities, it becomes possible to reduce the Vth variation component due to the impurity variation.

Next, a description is given of a semiconductor device and an integrated circuit of a first embodiment of the present invention. FIG. 9 is a cross-sectional view showing a configuration for a thin-film channel MISFET of this embodiment.

As shown in FIG. 9, an SOI structure is formed for a thin-film channel MISFET of this embodiment by sequentially forming an embedded oxide film 2 and a silicon thin-film 3 on a semiconductor substrate 1. An element separation region 4 is formed on the embedded oxide film 2 using trench separation. Source/drain diffusion layers 5 and 6 and a channel region 7 provided between the diffusion layers are formed on the silicon thin-film 3 within the element separation region 4. Impurities of a prescribed concentration are then uniformly introduced in a depth direction at the channel region 7. At the designed gate length, the volume concentration of this impurity is a concentration that minimizes variation in threshold voltage caused by variation in channel film thickness and impurity variation. The channel impurity concentration shown in FIG. 6 and FIG. 7 is given as an example. The concentration of impurities per unit area contained in the channel region 7 is proportional to the channel film thickness because the concentration of impurity contained in the channel region 7 is fixed. A gate electrode 9 is formed on the channel region 7 via a gate insulation film 8. A sidewall 10 is formed at a sidewall of the gate electrode 9. A transistor is then wired via a silicide region I provided respectively at the upper parts of the gate electrode 9 and the diffusion layers 5 and 6, respectively. Inter-layer insulation films, plugs, and wiring etc. are formed, which are not shown in the diagram, at upper parts of the transistor elements so as to provide an integrated circuit function. This embodiment is a semiconductor device having a thin-film Channel MISFET, configured as described above, and an integrated circuit having a plurality of the thin-film MISFETs. In this embodiment, impurities are introduced to the channel region in such a manner that the concentration of impurities per unit area contained in the channel region becomes larger for MISFETs with a thicker channel film thickness. In particular, this concentration is proportional to the channel film thickness.

A method for uniformly introducing impurities to the thin-film channel region is now described. The uniform introduction of impurities to the thin-film channel region can be implemented by using a method of performing channel injection split over a plurality of times, or by using doped epitaxial growth technology.

When, for example, impurities are introduced using channel injection, as shown in FIG. 8A, it is possible to introduce impurities uniformly in a depth direction of the thin-film channel region by implementing channel injection of differing average ranges over a number of times. At this time, it is necessary to set an impurity injection range to be sufficiently broader than a range of variation of the channel film thickness Tsi. It is therefore preferable for at least one-time ion injection in a plurality of times to reach an average range at a position deeper than the designed channel film thickness. In FIG. 8A, a silicon thin-film is formed on the embedded oxide film. A sacrifice oxide film is then provided on the silicon thin-film. Impurities are then introduced using ion injection from above the sacrifice oxide film. In this example, channel injection of different average ranges is implemented split up three times. A peak for impurity concentration of ion injection of the longest average range is positioned within the embedded oxide film. FIG. 8B is a diagram showing channel doping effects. FIG. 8B schematically shows canceling out of DIBL deviation using variations of channel film thickness by uniformly introducing a prescribed concentration of impurities in a depth direction of the thin-film channel. If the same type of impurities are used for the channel injection, a combination of a plurality of ion species is possible to be used.

It is possible to obtain a uniform impurity distribution by forming the thin-film channel region with the impurity doping epitaxial growth in which impurity raw material and silicon raw material are supplied at the same time. For example, it is preferable to simultaneously supply disilane (Si₂H₆), diborane (B₂H₂), (or phosphine (PH₃)) and bring about epitaxial growth using CVD (Chemical Vapor Deposition). It is also possible to interchange and supply the raw materials etc. using ALD (Atomic Layer Deposition) to bring about epitaxial growth. The impurity doping epitaxial growth can be carried out when the SOI substrate is made. Or it can be carried out by performing etching so that some silicon layer remains on the upper part of the SOI substrate, with impurity doping epitaxial growth taking place after this so as to give a prescribed body film thickness. Alternatively, if the silicon layer film thickness of the SOT substrate is sufficiently thinner than the designed channel film thickness, it is also possible to perform impurity doping epitaxial growth directly onto the original silicon layer.

Alternatively, it is also possible to form an SOI structure by using hetro-epitaxial growth to form a film (for example, silicon germanium etc.) that lattice-matches with the silicon substrate, perform silicon impurity-doped epitaxial growth, and then remove the hetro-epitaxial layer using etching. The etching portion is then back-filled using an embedded oxide film. It is therefore possible to obtain a thin-film channel region that has an impurity concentration that is uniform in the depth direction using this method.

The formed impurity concentration distribution and correlation between the channel film thickness and the channel impurity concentration per unit area can be confirmed using various methods. For example, impurity distribution in a channel depth direction can be analyzed via built-in potential observed from a sample cross-section by utilizing electron beam holography, SCAM (Scanning Capacitance Microscope ) or KPFM (Kelvin Prove Force Microscope). With the impurity concentration per unit area of the thin-film channel, it is possible to detect the concentration of impurities contained in the channel thin-film with high sensitivity by selectively exciting the thin-film region of the sample surface using an electron beam and then detecting characteristic x-rays. It is then possible to obtain the correlation of channel film thickness and channel impurity concentration per unit area across, for example, the inner surface of a wafer, by combining this method and a publicly known method for measuring channel film thickness.

According to this embodiment, it is possible to suppress variation in the threshold voltage caused by statistical variation from a designed value for channel film thickness and variation of concentration of impurities in the depth direction in an integrated circuit containing a plurality of thin-film channel MISFETs by introducing a prescribed volume concentration of impurities in a uniform manner into the channel region.

In the related art, it is preferable for the channel impurity concentration of a completely depleted MISFET having a thin-film channel to be of low concentration close to that of a perfect semiconductor. Because it is possible to suppress short channel effects in thin-film transistors where the channel film thickness is sufficiently thin and it can then be considered possible to improve mobility and reduce threshold voltage variation caused by variation of the position and number of impurities (impurity variation) by making the channel impurity concentration low. However, variation in the threshold voltage due to DIBL (Drain Induced Barrier Lowering) occurs even when the impurity concentration is zero, if there is statistical variation in the channel film thicknesses of MISFETs constituting an integrated circuit when semiconductor layer is manufactured. In the present invention, it is possible to reduce the variation in the threshold voltage caused by variation in channel film thickness by introducing a prescribed concentration of impurities into the channel.

Next, a description is given of a method for manufacturing a semiconductor device of a second embodiment of the present invention. FIGS. 10A to 10C are cross-sectional views showing an order of steps of a method for manufacturing this embodiment, and FIGS. 11D to 11F are cross-sectional views showing an order of steps for the method of manufacturing this embodiment continuing on from FIG. 10. The following is a description of an example of a method for manufacturing a P-type MOSFET. However, it is also possible to make an N-type MOSFET by appropriately selecting the ion species and injection energy etc.

First, as shown in FIG. 10A, an embedded oxide film 22 and a silicon thin-film 23 are sequentially formed one on top of the other on a silicon substrate 21. An element separation region 24 is then formed on the embedded oxide film 22 using trench separation.

Next, as shown in FIG. 10B, a sacrifice oxide film 25 is formed on the silicon thin-film 23 and the element separation region 24 within the defined element separation region 24. An N-type channel impurity is then uniformly introduced using ion injection from above the sacrifice oxide film 25 (refer to FIG. 8). For example, if the film thickness of the silicon thin-film 23 is 20 nm and the film thickness of the sacrifice oxide film 25 is in the order of 10 nm, arsenic is injected at an injection quantity in the order of 1×10¹² at/cm² at an energy of 7.5 keV. Arsenic is then injected at an injection quantity in the order of 2×10¹² at/cm² at an energy of 25 keV. After this, arsenic is injected at an injection quantity in the order of 4×10¹² at/cm² at an energy of 70 keV. It is therefore possible for arsenic of a concentration in the order of 1×10¹⁸ at/cm³ to be introduced in a uniform manner in the depth direction in the silicon thin-film 23. It is then possible to carry out annealing processing using a publicly known method in order to activate the channel impurities. In this event, it is preferable to carry out annealing processing using laser annealing etc. using conditions that do not promote the diffusion of the impurity so that the channel impurity is not diffused outwards or deposited. The sacrifice oxide film 25 is then peeled away.

Next, as shown in FIG. 10C, a gate insulation film 26 is formed on the silicon thin-film 23 and the element separation region 24. An electrode layer 27 of a film thickness of 1000 Angstroms is then formed. The electrode layer 27 is comprised of polysilicon, polysilicon germanium, or a laminated structure of polysilicon and poly silicon germanium. The electrode layer 27 can also be a metal gate electrode.

Next, the resist pattern obtained as a result of patterning is transferred to a hard mask formed on the electrode layer 27 and etching of the electrode layer 27 is carried out using this hard mask pattern. The hard mask is then removed from the polysilicon layer and, as shown in FIG. 11D, a gate electrode 28 comprised of polysilicon is formed.

Next, an oxide film of a film thickness of 50 to 1000 angstroms is formed. As shown in FIG. 11E, a sidewall 29 comprised of an oxide film is formed at a side surface of the gate electrode 28 using plasma etch-back. Next, ion injection is carried out taking the sidewall 29 as a mask and a source/drain impurity diffusion region 30 is formed. After this, heat treatment is carried out using a publicly known method and the impurities of the source/drain region are activated,

As shown in FIG. 11F, for example, a silicide region 31 is formed on the upper surface of the source, drain, and gate by performing silicide processing by depositing a metal such as Co or Ni and sintering using heat treatment. The thin-film channel MISFET of this embodiment shown in FIG. 9 is therefore completed as a result of the above steps.

By uniformly introducing a prescribed concentration of impurity to the channel region, it is possible to keep variation of Vth to a minimum even if the film thickness of the thin-film channel region varies for the MISFET of this embodiment made in the above manner (refer to FIG. 8B).

An example is shown only for the essential steps of the method for forming each part of this embodiment of the present invention. However, it is also possible for various steps, which are not disclosed in the embodiment of the present invention, to be included in the manufacture of an actual MOSFET. Further, the dimensions of each part, the energy for ion injection, and the injection quantity etc. can be modified within the technological scope of the present invention as can be understood from the scope of the patent claims of the present invention and by no means limit the scope of the present invention.

Next, a modified example of the second embodiment is described. In the following modified example, a method for manufacturing SOI MOSFET is disclosed where the concentration of impurities per unit area contained in the thin-film channel region is larger for MISFETs of a thicker channel film thickness and the impurity concentration per unit volume becomes greater in a depth direction from the channel surface.

First, a description is given of a first modified example of the second embodiment of the present invention. A description is now given with reference to FIG. 12 of a method for manufacturing a semiconductor device of this modified example. First, as shown in FIG. 12A, an embedded oxide film 42 and a silicon thin-film 43 are sequentially formed one on top of the other on a silicon substrate 41 using a method of the related art. An element separation region 44 is then formed using trench separation.

Next, as shown in FIG. 12B, a sacrifice oxide film 45 is formed within the defined element separation region 44. Channel impurities are then ion-injected from above the sacrifice oxide film 45 under the condition that an average range distance is positioned deeper than the silicon thin-film 43. As a result of this ion injection, the concentration per unit area of the impurity becomes greater as the channel film thickness becomes thicker. It is therefore possible to introduce impurity in such a manner that the impurity concentration per unit volume becomes greater in a depth direction from the channel surface (refer to FIG. 13).

In the related art, an impurity profile where the impurity concentration becomes lower at the channel surface is well-known as a so-called retrograde impurity distribution. However, the ion injection method and profile disclosed in this modified example differ from the publicly known example with regards to the following points. This method for introducing impurity has the characteristic property that the impurity concentration per unit area becomes larger for MISFETs where the channel film thickness becomes thicker. Further, the impurity concentration per unit volume at the bottom surface of the channel film is set to a concentration that minimizes variation of Vth caused by deviation of the channel film thickness and impurity variation. With regards to the relationship of the standard deviation σVth of the threshold voltage with respect to statistical variation from the designed values for volume concentration of the impurity and channel film thickness at the gate length, and variation of the volume concentration of the impurity in a depth direction from the channel film surface, the volume concentration distribution for the impurity at the channel film is such that a volume concentration that gives a minimum σVth is included at the bottom surface of the channel film. Further, when the channel impurities are redistributed as the result of a subsequent annealing step so that the impurity distribution finally becomes substantially uniform in a depth direction of the channel, the impurity distribution becomes the same as for the first embodiment. As a result of this impurity distribution, it is possible to suppress variation of Vth caused by statistical variation of the channel film thickness. The total amount of impurity within the channel's thin-film can be reduced compared to when uniform channel impurity distribution is adopted. It is therefore possible to suppress variation of Vth due to impurity variation. The manufacturing steps of FIG. 12B thereafter are the same as for the second embodiment and are therefore omitted.

Next, a description is given of a second modified example of the second embodiment of the present invention. A description is now given with reference to FIG. 14 of a method for manufacturing a semiconductor device of this modified example. First, as shown in FIG. 14A, an embedded oxide film 52 and a silicon thin-film 53 are sequentially formed one on top of the other on a silicon substrate 51 using a method of the related art. The silicon thin-film 53 is formed so as to be thinner than the film thickness of the device design. An element separation region 54 is then formed using trench separation.

Next, as in the second embodiment, impurity is introduced uniformly to the silicon thin-film 53 and annealing processing is carried out to implement crystalline recovery. A silicon epitaxial layer 55 is then selectively epitaxially grown on the silicon thin-film 53. The film thickness of the silicon epitaxial layer 55 is selected so that the total film thickness of the silicon thin-film 53 and the silicon epitaxial layer 55 becomes equal to the designed channel film thickness. Impurity is not introduced during epitaxial growth, or alternatively, impurity is introduced at a concentration lower than the impurity concentration within the silicon thin-film 53 (refer to FIG. 15). The manufacturing steps of FIG. 14B thereafter are the same as for the second embodiment and are therefore omitted.

The impurity concentration distribution of the channel region obtained in the above manner is shown in FIG. 15. As shown in FIG. 15, the concentration of impurity uniformly introduced at the silicon epitaxial layer close to the channel film surface is lower than the uniform impurity concentration within the silicon thin-film. The impurity concentration within the silicon thin-film is a concentration that minimizes the variation of Vth caused by the deviation in channel film thickness and the impurity variation. With regards to the relationship of the standard deviation σVth of the threshold voltage with respect to statistical variation from the designed values for volume concentration of the impurity and channel film thickness at the gate length, and variation of the volume concentration of the impurity in a depth direction from the channel film surface, the volume concentration distribution for the impurity at the channel film is such that a volume concentration that gives a minimum σVth is included at the bottom surface of the channel film. The SOI MOSFET obtained in this manner is capable of suppressing variation of Vth due to deviation of DIBL, and is capable of keeping variation of Vth due to impurity variation low compared to when a uniform channel impurity distribution is adopted.

Next, a description is given of a third modified example of the second embodiment of the present invention. A description is now given with reference to FIG. 16 of a method for manufacturing a semiconductor device of this modified example. First, as shown in FIG. 16A, an embedded oxide film 62, a diffusion prevention layer 63, and a silicon thin-film layer 65 are sequentially formed one on top of the other on a silicon substrate 61 using a method of the related art. An element separation region 64 is then formed using trench separation. For example, a nitride film, and an oxide film, or a film that is a combination thereof can be deposited as the diffusion prevention layer 63.

Next, a sacrifice oxide film layer 66 is formed on the silicon thin-film layer 65 and the element separation region 64 as shown in FIG. 16B. Impurities are then uniformly introduced into the silicon thin-film layer 65 in the same way as for the second embodiment. Annealing processing is then carried out under the condition that the impurities of the silicon thin-film layer 65 are diffused towards the outside of the sacrifice oxide film layer 66 and the impurity concentration of the surface of the silicon thin-film layer 65 is reduced. If the speed of diffusion of the channel impurity occurring at the embedded oxide film 62 is sufficiently slow compared to the sacrifice oxide film layer 66, the diffusion prevention layer 63 does not have to be formed. The manufacturing steps of FIG. 16B thereafter are the same as for the second embodiment and are therefore omitted.

The impurity concentration distribution of the channel region obtained in the above manner is shown in FIG. 17. As shown in FIG. 17, the concentration in a channel depth direction of impurity introduced into the channel thin-film is a fixed value at a region close to the diffusion prevention layer and reduces as the channel film surface is approached due to the effects of outward diffusion. The impurity concentration occurring at a region of a depth close to the diffusion prevention layer is set to a concentration that minimizes the variation of Vth caused by deviation of the channel film thickness and impurity variation. With regards to the relationship of the standard deviation σVth of the threshold voltage with respect to statistical variation from the designed values for volume concentration of the impurity and channel film thickness at the gate length, and variation of the volume concentration of the impurity in a depth direction from the channel film surface, the volume concentration distribution for the impurity at the channel film is such that a volume concentration that gives a minimum σVth is included at a region close to the diffusion prevention layer of the channel film. The SOI MISFET obtained in this manner is capable of suppressing variation in Vth due to the deviation of DIBL, and is capable of keeping variation of Vth due to impurity variation low compared to when a uniform channel impurity distribution is adopted.

Next, a description is given of a fourth modified example of the second embodiment of the present invention. A description is now given with reference to FIG. 18 of a method for manufacturing a semiconductor device of this modified example. First, as shown in FIG. 18A, an embedded oxide film 72 and a silicon thin-film 73 are sequentially formed one on top of the other on a silicon substrate 71 using a method of the related art. An element separation region 74 is then formed using trench separation. Next, a sacrifice oxide film layer 75 is formed and impurities are introduced in a substantially uniform manner at the silicon thin-film 73 in the same way as for the second embodiment.

The sacrifice oxide film layer 75 is then removed by etching as shown in FIG. 18B. An oxide film layer 76 including an impurity of an opposite conductive type to the impurity in the silicon thin-film 73 is deposited. The impurity within the oxide film layer 76 is then diffused at the surface of part of the silicon thin-film 73 by annealing. The oxide film layer 76 is then removed by etching. The manufacturing steps of FIG. 18B thereafter are the same as for the second embodiment and are therefore omitted.

The impurity concentration distribution of the channel region obtained in the above manner is shown in FIG. 19. As shown in FIG. 19, the concentration in a channel depth direction of impurity introduced into the channel film is a fixed value at a region close to the embedded oxide film and reduces as the channel film surface is approached due to the introduction of impurity of an opposite conductive type to that of the channel impurity at the channel film surface. The impurity concentration at a region of a depth close to the embedded oxide film is set to a concentration that minimizes the variation of Vth caused by deviation of the channel film thickness and impurity variation. Namely, with regards to the relationship of the standard deviation σVth of the threshold voltage with respect to statistical variation from the designed values for volume concentration of the impurity and channel film thickness at this gate length, and variation of the volume concentration of the impurity in a depth direction from the channel film surface, the volume concentration distribution for the impurity at the channel film is such that a volume concentration that gives a minimum σVth is included at the bottom surface of the channel film. With the SOI MISFET obtained in this manner, the effective impurity concentration of the channel thin-film surface is reduced by introducing an impurity of an opposite conductive type to the conductive type of the channel impurity to the channel thin-film surface. It is therefore possible to suppress variation of Vth due to deviation of DIBL. It is also possible to keep variation of Vth due to impurity variation low compared to when a uniform channel impurity distribution is adopted.

In the first to fourth modified examples of the second embodiment described above, examples are given of forming a planar SOI MISFET so as to give a function where channel impurity concentration per unit area is convex in a downward direction with respect to channel film thickness.

Next, a description is given of a method for manufacturing a semiconductor device of a third embodiment of the present invention. In this embodiment, a method of manufacturing a FinFET is disclosed where the concentration per unit area of impurity contained in the thin-film channel region becomes larger for MISFETs where the channel film thickness is thicker and the impurity concentration per unit volume is set to become greater in a depth direction from the channel film surface.

A description is now given of a method for manufacturing a semiconductor device of this embodiment with reference to FIGS. 20 and 21. FIGS. 20A to 20D are cross-sectional views showing the order of steps of the method for manufacturing the semiconductor device of the third embodiment. FIGS. 21E to 21G are cross-sectional views showing the order of steps of the manufacturing method continuing on from FIG. 20. First, as shown in FIG. 20A, an embedded oxide film 82, and a silicon film 83 introduced with impurities of a prescribed concentration in a uniform manner, are sequentially formed one on top of the other on a silicon substrate 81 using a method of the related art. The silicon film 83 can be formed by forming a silicon layer of a thin-film SOI to be thick using impurity doping in epitaxial growth. Alternatively, the silicon film 83 can be formed by uniformly introducing impurities to a silicon layer of a thick film SOI prepared in advance by performing channel injection a plurality of times of different average ranges or by carrying out thermal diffusion. The concentration of impurities introduced to the channel region is a concentration that minimizes the variation of Vth caused by deviation of the channel film thickness and impurity variation. With regards to the relationship of the standard deviation σVth of the threshold voltage with respect to statistical variation from the designed values for volume concentration of the impurity and channel film thickness at the gate length, and variation of the volume concentration of the impurity in a depth direction from the channel film surface, the volume concentration distribution for the impurity at the channel film is such that a volume concentration that gives a minimum σVth is included.

Further, a hard mask layer is formed on the silicon film 83. The hard mask layer is comprised of, for example, silicon dioxide, silicon nitride, or a film that is a combination thereof, etc. Resist is then applied, exposed, and developed, to give a resist pattern. The hard mask layer is then etched taking the resist pattern as a mask and a hard mask 84 is formed (refer to FIG. 20B).

Next, the silicon film 83 is etched taking the hard mask 84 as a mask pattern so as to form the shape of a fin 85 as shown in FIG. 20C.

Next, a sacrifice oxide film layer 86 is deposited, as shown in FIG. 20D. The impurity is then diffused outwards from the surface of the fin 85 towards the sacrifice oxide film layer 86 by carrying out annealing. The impurity concentration of the surface of the fin 85 is therefore reduced as shown in FIG. 22. At the sacrifice oxide film layer 86, it is preferable for the diffusion speed of the impurity introduced to the silicon layer 83 to be fast compared to that of the embedded oxide film 82 and the hard mask 84. Although not shown in the diagrams, it is also appropriate to provide a diffusion prevention layer between the embedded oxide film 82 and the fin 85. When outward diffusion of the impurity towards the hard mask 84 is significantly large, in order to compensate for this, it is preferable to additionally inject impurity of the same type perpendicularly from above the hard mask 84.

Next, the sacrifice oxide film layer 86 is etched and a gate oxide film 87 is formed on the surface of the fin 85 (FIG. 21E). It is also possible to etch the hard mask 84 before forming the gate oxide film 87, but this is not essential. The case where the hard mask 84 is etched is shown in FIG. 21E.

Next, as shown in FIG. 21 F, a prescribed pattern is processed using lithography after depositing the gate electrode film and a gate electrode 88 is formed.

A sidewall 89 is then formed at a side part of the gate electrode 88. Ion injection is then carried out taking the sidewall 89 as a mask. A self-aligning source/drain diffusion region 90 is then formed. The configuration for the FinFET of this embodiment is then complete, as shown in FIG. 21G.

With the FinFET of this embodiment made in the above manner, the concentration per unit area of impurity contained in the thin-film channel (fin) region becomes larger for MISFETs of a thicker fin film thickness. It is possible to suppress the variation of Vth caused by statistical variation of the channel film thickness and impurity variation. It is also possible to reduce the total amount of impurity in the channel thin-film compared to when a uniform channel impurity distribution is adopted. This makes it possible to keep variation of Vth due to impurity variation low.

It is also possible for the method of introducing impurities to the channel region of a FinFET to be applied to methods employing channel injection as with planar SOI's. Namely, as shown in FIG. 23, it is possible for the method of introducing channel impurities to carry out ion injection from only one side of the fin, with the average range then reaching the outer side on the opposite side of the fin. In this case, comparing with planar SOI FETs, the channel film thickness is defined as the fin width, and the depth within the channel region is defined as the distance when the ion injection surface of the channel region is taken to be the top surface.

In addition to the above, various cross-sectional shapes such as a π shape, a Ω shape, and a gate-all-around shape are possible for the FinFET. In any of these cases, the introduction of channel impurities using the same method as for the embodiments is possible and it is possible to reduce statistical variation of Vth as a result.

Next, a description is given of a semiconductor device of a fourth embodiment of the present invention. In this embodiment the present invention is implemented using a planar double-gate FET. FIG. 24 is a cross-sectional view showing a configuration for a planar double-gate FET of the fourth embodiment of the present invention. In this embodiment, impurities are introduced to the thin-film channel region in such a manner that the concentration per unit area of impurity contained in the thin-film channel region becomes larger for MISFETs of a thicker channel film thickness.

As shown in FIG. 24, with the planar double-gate FET of this embodiment, an embedded oxide film 92 is formed on a semiconductor substrate 91. A source region 93, a drain region 94, and a thin-film channel region 95 provided between the source region 93 and the drain region 94 are formed on the embedded oxide film 92. A thin-film channel region 95 is formed so as to be sandwiched between a pair of vertically opposing gate electrodes 97 via the gate insulation films 96, with the gate electrodes 97 formed below contacting with the surface of the embedded oxide film 92. Further, gate sidewalls 98 are formed at the side surfaces of the gate electrodes 97 so as to separate the source region 93 and the drain region 94. Gate insulation films 96 are then arranged between the gate sidewalls 98 and the thin-film channel region 95. Wiring is then provided at each of the regions for the source, drain, and gate electrodes. Interlayer insulation films, plugs, and wiring etc. are formed at upper parts of the transistor elements so as to provide an integrated circuit function (not shown). This embodiment is a semiconductor device having a planar double-gate FET configured in the above manner, and an integrated circuit having a plurality of such planar double-gate FET's.

With the planar double gate FET made in this manner, the point of introducing impurities of a concentration that minimizes variation of Vth caused by deviation of channel film thickness and impurity variation in the thin-film channel region is the same as for the first to third embodiments. It is also possible to effectively suppress variation of Vth by reducing the channel surface impurity concentration. Further, it is possible to use publicly-known methods for the ion injection method, and in addition, it is possible to introduce impurities to the channel region using the methods disclosed in the first to third embodiments.

In the above, a description is given noting the method of introducing impurities to the thin-film channel in any of the examples disclosed in the first to fourth embodiments of the present invention. Various modifications can be made to the methods for forming each part other than the channel region within the technological scope of the present invention as can be understood from the scope of the patent claims of the present invention. For example, the source/drain section can have a film thickness thicker the thin-film channel region, can be formed of metal, and can have a so-called Schottky source/drain structure. Polysilicon can also be used as the material for the gate electrodes, and metal having an appropriate work function can be used.

### INDUSTRIAL APPLICABILITY

The present invention is applicable to an integrated circuit including a MISFET having a thin-film channel.

1-20. (canceled)

21. An integrated circuit having a plurality of MISFETs that include:
a semiconductor layer having a channel region provided between a source and a drain, the semiconductor layer being formed on an insulation film, a gate insulation film being in contact with the channel region; and
a gate being in contact with the gate insulation film;
wherein the channel region contains impurities of such a volume concentration that a standard deviation σVth of a threshold voltage, which changes due to variation of the thickness of the channel region and variation of the impurities, becomes a minimum, wherein such volume concentration that a standard deviation σVth of a threshold voltage becomes a minimum is within a range that accords to a gate length of the gate.

22. The integrated circuit according to claim 21, wherein design values of thicknesses of the respective channel regions of the plurality of MISFETs are the same as each other, and the difference in the thickness of the channel region among the respective MISFETs depends on the statistical variation from a design value.

23. The integrated circuit according to claim 21, wherein volume concentration Nch for the impurities that makes the standard deviation σVth of the threshold voltage minimum for a gate length L of a range of 15 to 80 nm is within a range that accords to the gate length and that satisfies −c≦log₁₀(Nch)+a·log₁₀(L)−b≦c (where a=1.33, b=19.9, and c=0.4).

24. The integrated circuit according to claim 21, wherein one surface of the channel region of each of the MISFETs is in contact with the gate insulation film and an other surface thereof is in contact with the insulation film, and volume concentration of the impurities in a depth direction from said one surface is constant regardless of the depth.

25. The integrated circuit according to claim 21, wherein one surface of the channel region of each of the MISFETs is in contact with the gate insulation film and an other surface thereof is in contact with the insulation film, and volume concentration of the impurities at a region in vicinity to said other surface of the channel region is higher than that at the region in vicinity to said one surface of the channel region.

26. The integrated circuit according to claim 25, wherein the volume concentration at a region in proximity to said other surface of the channel region is a volume concentration that makes the standard deviation σVth of the threshold voltage a minimum.

27. The integrated circuit according to claim 21, wherein each of the MISFETs is double-gate FET, and the volume concentration of the impurities in a film thickness direction from said one surface of the channel region is low in the vicinity of said one surface of the channel region and high in the vicinity of said other surface.

28. The integrated circuit according to claim 21, wherein each of the MISFETs is FinFET, and the volume concentration of the impurities is low in the vicinity of both surfaces and high at a median point that is equidistant from both surfaces.

29. A method of manufacturing a semiconductor device having a plurality of MISFETs that include: a semiconductor layer having a channel region provided between a source and a drain, the semiconductor layer being formed on an insulation film, a gate insulation film being in contact with the channel region; and a gate being in contact with the gate insulation film, the method comprising a step of introducing impurities of such a volume concentration that a standard deviation σVth of a threshold voltage, which changes due to variation of the thickness of the channel region and variation of the impurities, becomes a minimum, wherein such volume concentration that a standard deviation σVth of a threshold voltage becomes a minimum is within a range that accords to a gate length of the gate.

30. The method of manufacturing a semiconductor device according to claim 29, wherein the step of introducing the impurities is implemented by performing ion injection a plurality of times at different average range distances.

31. The method of manufacturing a semiconductor device according to claim 30, wherein the step of introducing the impurities includes ion injection in which average range distance of ion is larger than the thickness of the channel region.

32. The method for manufacturing a semiconductor device according to claim 29, wherein each of the MISFETs is FinFET, and in the step of introducing the impurities, ion injection is implemented from one surface of the channel region and the step of introducing the impurities includes ion injection in which average range distance of ion is larger than the thickness of the channel region.

33. The method of manufacturing a semiconductor device according to claim 29, further comprising a channel film growth step of growing the channel film by epitaxial growth, wherein the step of introducing the impurities is carried out at the same time as the channel film growth step by concurrently supplying a silicon material and an impurity material.

34. The method of manufacturing a semiconductor device according to claim 29, wherein the step of introducing the impurities includes a step of forming a sacrificial oxide film being in contact with both surfaces of the channel region and externally dispersing the impurities from both surfaces of the channel region to the sacrificial oxide film, to lower the volume concentration of the impurities in the region in vicinity to both surfaces of the channel region.
